(19) United States
(12) Patent Application Publication
(10) Pub. No.: US 2009/0127760 A1
(43) Pub. Date: May 21, 2009

(54) HOLDING DEVICE FOR HOLDING WORKPIECES AND VACUUM DEPOSITION APPARATUS USING SAME

(75) Inventor: Chung-Pei Wang, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/110,560

(22) Filed: Apr. 28, 2008

(30) Foreign Application Priority Data
Nov. 20, 2007 (CN) 200710202601.0

(51) Int. Cl. B25B 11/00; C23C 16/00

(52) U.S. Cl. 269/21; 118/715

(57) ABSTRACT

A holding device for workpieces, is provided. The holding device includes a holder and a suction device. The holder has a chamber, a top panel and a plurality of through holes defined in the top panel. The through holes are in communication with the chamber. The top panel is configured for supporting the workpieces over the respective through holes. The suction device is coupled to the chamber and is configured for pumping out air in the chamber, such that an atmospheric pressure of the chamber is lower than that of an exterior of the chamber, thereby holding the workpieces. A vacuum deposition apparatus using the holding device is also provided.

### BACKGROUND

1. Technical Field

The present invention relates to a holding device for holding workpieces, and a vacuum deposition apparatus using the holding device.

2. Description of Related Art

During production of a product or a semi-finished product, holding devices for holding workpieces are widely used. Such workpieces can be, for example, small size glass substrates for filters. Such glass substrates were preformed from a large piece of glass by an incision process, and are required to go through a series of post treatments according to need, such as vacuum deposition for optical films.

A typical holding device for a workpiece during vacuum deposition for optical films, may include two clamping portions. The clamping portions cooperate to clamp a periphery of the workpiece. However, the workpiece may be too small to be steadily clamped. In addition, the clamping portions may contact with the workpiece at only two points, this results that stress may be easily generated in the workpiece during the vacuum deposition for optical films.

What is needed, therefore, is a holding device, which is capable of steadily holding workpieces, and a vacuum deposition apparatus using the holding device.

### SUMMARY

An exemplary holding device for workpieces, is provided. The holding device includes a holder and a suction device. The holder has a chamber, a top panel and a plurality of through holes defined in the top panel. The through holes are in communication with the chamber. The top panel is configured for supporting the workpieces over the respective through holes. The suction device is coupled to the chamber and is configured for pumping out air in the chamber, such that an atmospheric pressure of the chamber is lower than that of an exterior of the chamber, thereby holding the workpieces.

An exemplary vacuum deposition apparatus for forming optical films on workpieces, is provided. The vacuum deposition apparatus includes a vacuum deposition chamber, deposition means, a holder and a suction device. The holder disposed in the vacuum deposition chamber. The holder has a chamber, a top panel and a plurality of through holes defined in the top panel. The through holes are in communication with the chamber. The top panel is configured for supporting the workpieces over the respective through holes. The suction device is coupled to the chamber and is configured for pumping out air in the chamber, such that an atmospheric pressure of the chamber is lower than that of an exterior of the chamber, thereby holding the workpieces.

Other advantages and novel features of the present holding device and vacuum deposition apparatus will become more apparent from the following detailed description of embodiment when taken in conjunction with the accompanying drawings.

### BRIEF DESCRIPTION OF THE DRAWINGS

Many aspects of the holding device and vacuum deposition apparatus can be better understood with reference to the following drawings. The components in the drawings are not necessarily drawn to scale, the emphasis instead being placed upon clearly illustrating the principles of the present holding device. Moreover, in the drawings, like reference numerals designate corresponding parts throughout the several views.

FIG. 1 is a schematic view of a holding device in accordance with a first embodiment of the present invention;

FIG. 2 is a schematic view showing the workpieces placed on the holes shown in FIG. 1; and

FIG. 3 is a schematic view of a holding device in accordance with a second embodiment of the present invention.

### DETAILED DESCRIPTION OF THE PREFERRED EMBODIMENTS

Embodiments of the present holding device and vacuum deposition apparatus will now be described in detail below and with reference to the drawings.

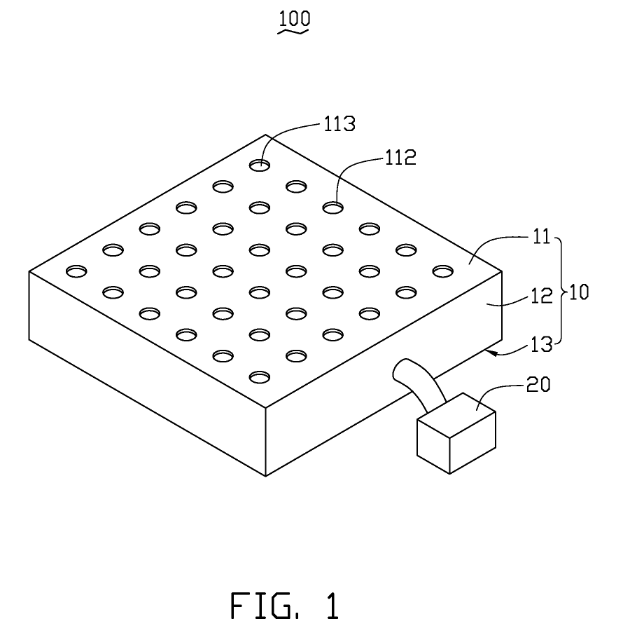

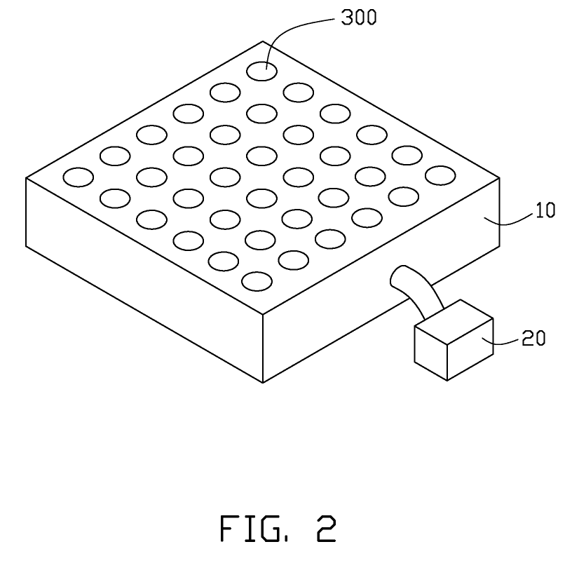

Referring to FIGS. 1 and 2, an exemplary holding device 100 in accordance with a first embodiment, is provided. The holding device 100 is configured for holding the workpieces 300.

The workpieces 300 can be, for example, glass substrates for filters. Such workpieces 300, which are small and in a round shape, were preformed from a large piece of glass by an incision process. The workpieces 300 are required to go through vacuum deposition for optical films. The holding device 100 includes a holder 10 and a suction device 20.

The holder 10 is mainly in a rectangular shape, and has a top panel 11, a bottom panel 12 and four side walls 13. The top panel 11, bottom panel 12 and four side walls 13 cooperatively form a chamber 113 therein. A number of through holes 112 are defined in the top panel 11, and are in communication with the chamber 113. The through holes 112 each are in a ring shape, and are equidistantly spaced from each other. A width of each of the through holes 112, i.e., a diameter thereof, is slightly smaller than that of the workpieces 300.

The suction device 20 is arranged adjacent to a side wall 13. The suction device 20 is coupled to the chamber 113 of the holder 10.

The holding device 100 is capable of steadily holding the workpieces 300 according to the steps as follows:

firstly, placing the workpieces 300 on the top panel 11 over the respective through holes 112, i.e., covering the each of the through holes 112 with one of the workpieces 300, in this way, the chamber 113 is isolated from outside;

secondly, pumping out air in the chamber 113 using the suction device 20, in this way, atmospheric pressure of the chamber 113 is lower than that of outside, and thus, the workpieces 300 will be steadily held thereon.

The holder 10 can be disposed in a vacuum deposition chamber (not shown), thus the workpieces 300 held by the holder 10 can go on the vacuum deposition for optical films. The vacuum deposition chamber may be a chamber equipped with a vacuum pump. The surfaces of the workpieces 300, which are exposed to outside, then would be deposited the optical films by a deposition means, such as an evaporation coater. Due to surface contact with the holder 10, stress exists in each of the workpieces 300 after the vacuum deposition can be reduced.

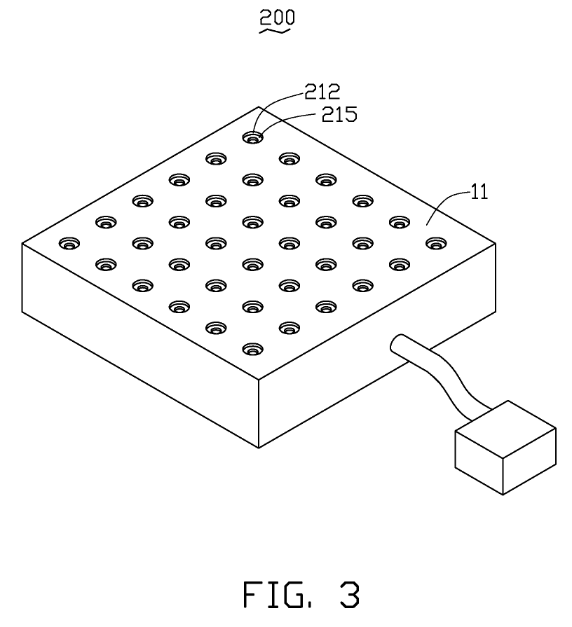

Referring to FIG. 3, an exemplary holding device 300 in accordance with a second embodiment, is provided. The holding device 200 is essentially similar to the holding device 100 illustrated above, however, the top panel 11 has a ring-shaped step 215 in the each of the through holes 212. A diameter of each of the steps 215 corresponds to that of the respective workpieces 300 so as to place the workpieces 300 on the steps 215 of the through holes 212.

It is understood that the above-described embodiments are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A holding device for holding workpieces, comprising:
a holder having a chamber, a top panel and a plurality of through holes defined in the top panel, the through holes in communication with the chamber, the top panel configured for supporting the workpieces over the respective through holes; and
a suction device coupled to the chamber and configured for pumping out air in the chamber, such that an atmospheric pressure of the chamber is lower than that of an exterior of the chamber, thereby holding the workpieces.

2. The holding device as described in claim 1, wherein the holder has a bottom panel opposite to the top panel and four side walls connected between the top panel and the bottom panel.

3. The holding device as described in claim 2, wherein the suction device is coupled to one of the side walls of the holder.

4. The holding device as described in claim 1, wherein the through holes are equidistantly spaced from each other.

5. The holding device as described in claim 1, wherein the top panel has a step formed in each of the through holes.

6. A vacuum deposition apparatus for forming optical films on workpieces, comprising:
a vacuum deposition chamber;
deposition means for forming optical films on the workpieces;
a holder disposed in the vacuum deposition chamber, the holder having a chamber, a top panel and a plurality of through holes defined in the top panel, the chamber in communication with the through holes, the top panel configured for supporting the workpieces over the respective through holes; and
a suction device coupled to the chamber and configured for pumping out air in the chamber, such that an atmospheric pressure of the chamber is lower than that of an exterior of the chamber, thereby holding the workpieces.

7. The vacuum deposition apparatus as described in claim 6, wherein the holder has a bottom panel opposite to the top panel and four side walls connected between the top panel and the bottom panel.

8. The vacuum deposition apparatus as described in claim 7, wherein the suction device is coupled to one of the side walls of the holder.

9. The vacuum deposition apparatus as described in claim 6, wherein the through holes are equidistantly spaced from each other.

10. The vacuum deposition apparatus as described in claim 6, wherein the top panel has a step formed in each of the through holes.
